(19) United States
(12) Patent Application Publication
(10) Pub. No.: US 2006/0027169 A1
(43) Pub. Date: Feb. 9, 2006

(54) Method and system for substrate temperature profile control

(75) Inventors: Yuji Tsukamoto, Wilmington, MA (US); Paul Moroz, Marblehead, MA (US); Nobuhiro Iwama, Lexington, MA (US); Shinji Hamamoto, Salem, MA (US)

Correspondence Address: OBLON, SPIVAK, MCCLELLAND, MAIER & NEUSTADT, P.C., 1940 DUKE STREET, ALEXANDRIA, VA, 22314, US

(73) Assignee: TOKYO ELECTRON LIMITED, Minato-ku (JP)

(21) Appl. No.: 10/912,182

(22) Filed: Aug. 6, 2004

(51) Int. Cl. C23C 16/00

(52) U.S. Cl. 118/724

(57) ABSTRACT

A method and system are provided for rapid temperature profile control of the upper surface of a substrate holder providing a specified uniformity or specified non-uniformity of the temperature profile on that surface. The substrate holder includes a first fluid channel positioned in a first thermal zone, utilizing a heat transfer fluid at a specified flow rate and at a specified temperature, to control the temperature profile of the first thermal zone of the surface of the substrate holder. A second fluid channel positioned in a second thermal zone of the substrate holder, utilizing a heat transfer fluid at a specified flow rate and at a specified temperature, is configured to control the temperature profile of the second thermal zone of the surface of the substrate holder.

### CROSS REFERENCE TO RELATED APPLICATIONS

The present invention is related to U.S. patent application Ser. No. 10/721,500, filed Nov. 14, 2003, U.S. Provisional Application Ser. No. 60/458,043, filed Mar. 28, 2003, and U.S. application Ser. No. 10/168,544, filed on Jul. 2, 2002, the entire contents of these applications is incorporated herein by reference.

### FIELD OF THE INVENTION

The present invention relates to a method and system for temperature profile control of a substrate, and more particularly to a substrate holder for temperature profile control of a substrate.

### BACKGROUND OF THE INVENTION

It is known in semiconductor manufacturing and processing that various processes, including for example etch and deposition processes, depend significantly on the temperature of the substrate. For this reason, the ability to uniformly control the temperature of a substrate is an essential requirement of a semiconductor processing system. The temperature of a substrate is determined by plasma processes, such as ion bombardment, as well as thermal radiation, thermal conduction, and chemical processes occurring at the surface of the substrate, etc. Providing a proper temperature to the upper surface of the substrate holder can be utilized to control the temperature of the substrate.

To provide a proper temperature to the substrate holder many substrate holders utilize a temperature control channel having a single inlet and a single outlet, wherein the channel permits the flow of a heat-transfer fluid that can transfer heat to or remove heat from the upper surface of the substrate holder. The present inventors have recognized that such a single channel substrate holder provides inaccurate temperature control in some instances.

For example, a backside temperature controlling gas can be used to provide thermal conductivity between the substrate holder and the substrate. When the backside gas is utilized the pressure of the gas is typically not uniform. This non-uniformity of pressure of the backside gas can result in uneven heat transfer between the substrate and the substrate holder. A single temperature control channel in the substrate holder cannot always provide adequate temperature control to ensure the temperature profile of the substrate is at specified levels when backside gas pressure is not uniform.

In addition, many times, not only the temperature of the upper surface of the substrate holder is of importance but also spatial distribution of temperature (i.e., a particular temperature profile) is required to obtain desired process results. For example, it has been found that uniform etching or deposition can include adjusting temperature profile on the upper surface of the substrate holder in order to compensate for other thermal non-uniformities. However, a single temperature control channel substrate holder applies the same temperature control across the entire area of the substrate and therefore cannot provide such an accurate temperature profile.

In addition to the inaccurate temperature control noted above, the present inventors have further recognized that conventional temperature control mechanisms provide an inadequate temperature change rate for some processes. Many processes in the semiconductor industry require multi-step processing, each step requiring different temperatures, gas compositions, RF powers, etc. Such multi-step processes benefit when sequential processes are accomplished quickly within the same vacuum chamber. In order to achieve this goal, substrate holders must be capable of rapid change to heat transfer characteristics. Customarily, a chiller controls the temperature of the heat-transfer fluid that circulates through the substrate holder. The chiller can require significant time to change the temperature of the heat-transfer fluid, dependant on the plasma process.

### SUMMARY OF THE INVENTION

Accordingly, one object of the present invention is to reduce or solve any of the above-described or other problems with conventional temperature control.

Another object of the current invention is to provide temperature profile control to the upper surface of a substrate holder.

Still another object of the current invention is to provide rapid changes in the temperature of a substrate holder when required by the process or processes.

These and/or other objects may be provided by a substrate holder and method for controlling the temperature of a substrate in accordance with the present invention. According to one aspect of the invention, a system for controlling the temperature of a substrate includes a substrate holder having a first fluid channel located in a first thermal zone in the substrate holder and a second fluid channel located in a second thermal zone in the substrate holder. A first heat exchanger is coupled to the first fluid channel and configured to supply a first heat transfer fluid at a first flow rate to the first fluid channel, and a second heat exchanger is coupled to the second fluid channel, and configured to supply a second heat transfer fluid at a second flow rate to the second fluid channel.

According to another aspect of the invention, a method of controlling temperature of a substrate held on a substrate holder includes providing a first heat transfer fluid to a first thermal zone in the substrate holder, providing a second heat transfer fluid to a second thermal zone in the substrate holder, and controlling a flow rate of the first heat transfer fluid or the second heat transfer fluid or both to control a temperature profile of the substrate.

Still another aspect of the invention includes a system for controlling the temperature of a substrate including a substrate holder having a first thermal zone in the substrate holder, and a second thermal zone in the substrate holder. Also provided is means for independently controlling a temperature of the first and second thermal zones of the substrate holder to provide a temperature profile for the substrate holder.

### BREIF DESCRIPTION OF THE DRAWINGS

In the accompanying drawings:

FIG. 1 depicts a simplified block diagram of a plasma processing system having a substrate holder according to an embodiment of the invention;

FIG. 2 depicts a simplified block diagram of a plasma processing system having a substrate holder according to another embodiment of the invention;

FIG. 3 depicts a simplified block diagram of a plasma processing system having a substrate holder according to another embodiment of the invention;

FIG. 4 depicts a simplified block diagram of a plasma processing system having a substrate holder according to another embodiment of the invention;

FIG. 5 depicts a simplified block diagram of a plasma processing system having a substrate holder according to another embodiment of the invention; and

FIG. 6 depicts a method of controlling the temperature of a substrate on a substrate holder in a processing system according to an embodiment of the present invention.

### DETAILED DESCRIPTION OF THE PREFERRED EMBODIMENTS

In the following description, in order to facilitate a thorough understanding of the invention and for purposes of explanation and not limitation, specific details are set forth, such as a particular geometry of the substrate holder and various shapes of the temperature control elements in the substrate holder. However, it should be understood that the invention may be practiced in other embodiments that depart from these specific details.

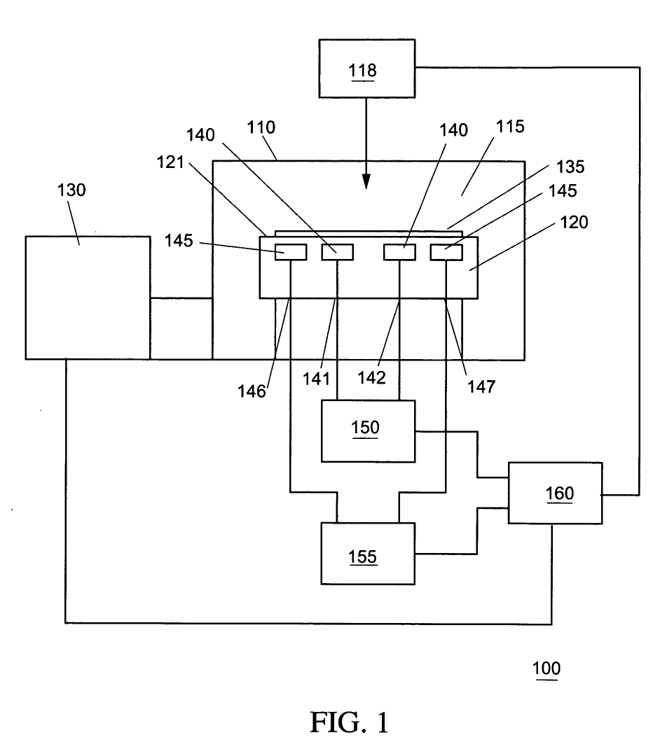

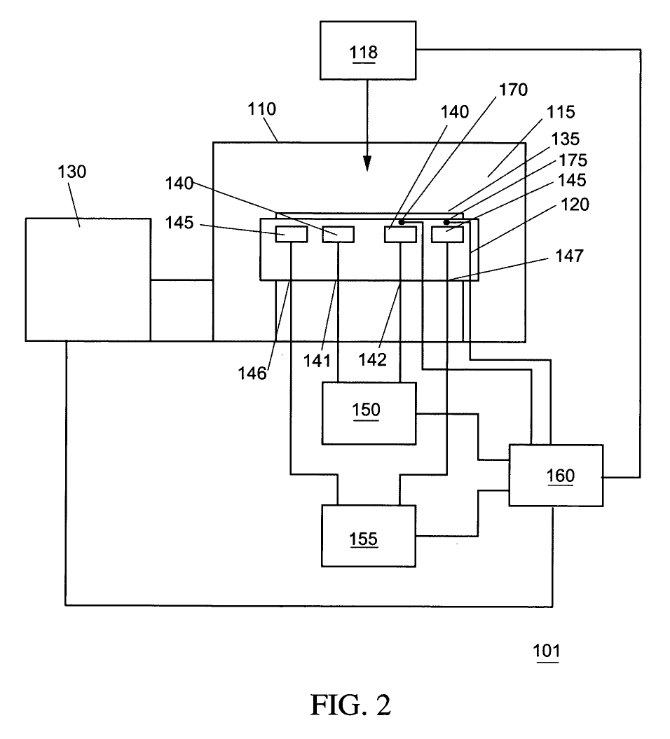

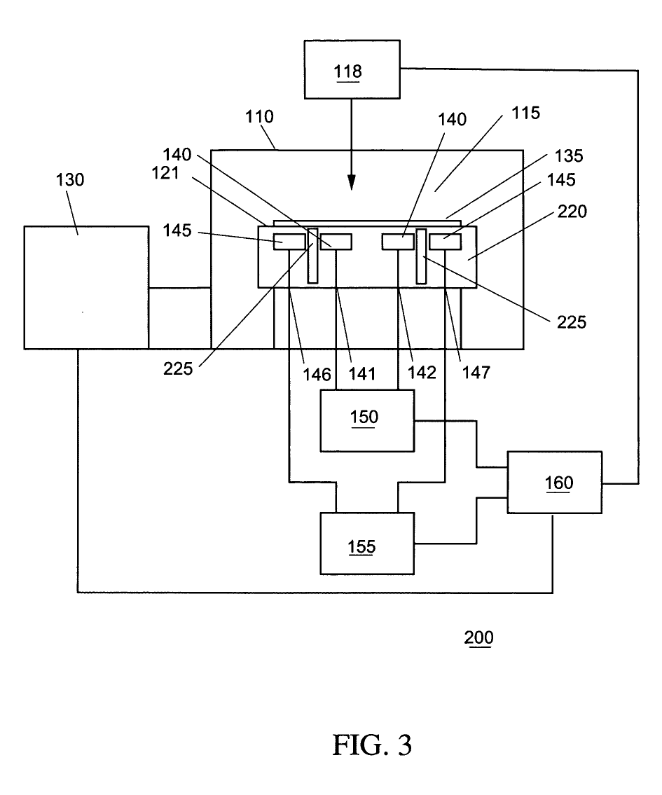

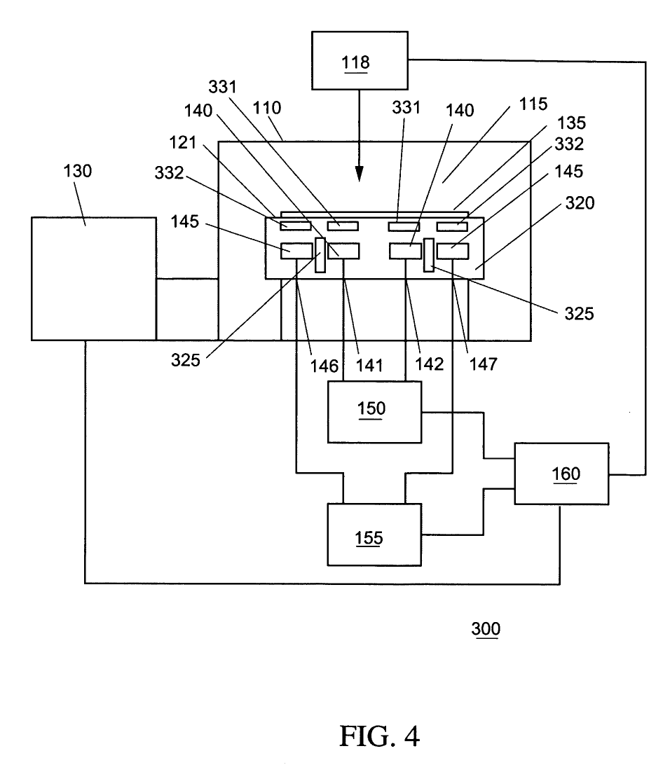

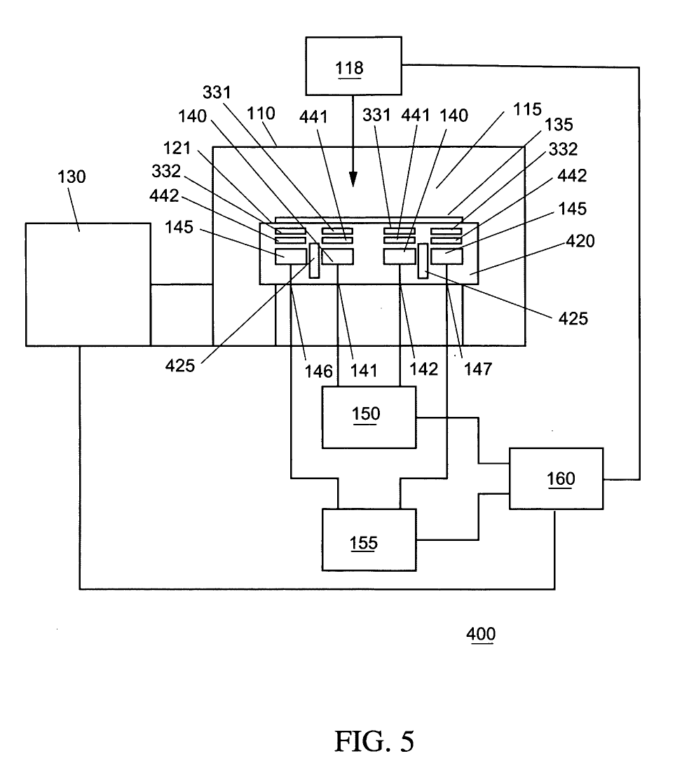

According to an embodiment of the present invention, a material processing system 100 is depicted in FIG. 1 that includes a process tool 110 having a substrate holder 120 and a substrate 135 supported thereon. The substrate holder 120 is configured to provide at least two thermal zones arranged within the substrate holder 120 in order to provide temperature profile control and/or rapid adjustment of the substrate temperature within the material processing system 100. The thermal zones each can, for example, comprise a fluid channel for circulating a heat transfer fluid at a pre-specified flow rate and temperature with or without additional temperature control elements such as a resistive heating element or elements, and/or some number of thermo-electric devices, etc. For clarity of presentation, fluid channels in the respective substrate holder represent thermal zones, and are exemplified in FIG. 1, FIG. 2, FIG. 3, FIG. 4, and FIG. 5.

In the illustrated embodiment depicted in FIG. 1, the material processing system 100 can facilitate either plasma etching or non-plasma etching. Alternately, the material processing system 100 includes a photoresist coating chamber such as a heating/cooling module in a photoresist spin coating system that may be utilized for post-adhesion bake (PAB) or post-exposure bake (PEB), a photoresist patterning chamber such as ultraviolet (UV) lithography system, a dielectric coating chamber such as spin-on glass (SOG) system, spin-on dielectric (SOD) system, a deposition chamber such as chemical vapor deposition (CVD) system, a physical vapor deposition (PVD) system, a plasma enhanced chemical vapor deposition (PECVD), an atomic layer deposition (ALD) system, or a rapid thermal processing (RTP) chamber such as RTP system for thermal annealing.

According to the illustrated embodiment depicted in FIG. 1, the material processing system 100 includes process tool 110, with a process volume 115, having substrate holder 120, upon which substrate 135 to be processed is affixed, gas injection system 118, and vacuum pumping system 130. Substrate 135 can be a semiconductor wafer or a liquid crystal display (LCD).

The substrate holder 120 is configured to support substrate 135, and control the temperature thereof. The substrate holder 120 comprises a first fluid channel 140, which is substantially circular, positioned in a central thermal zone of substrate holder 120, and a second fluid channel 145 in a peripheral thermal zone of substrate holder 120, concentrically arranged about the first fluid channel 140. The first fluid channel 140 is configured to circulate a first heat-transfer fluid provided at a corresponding inlet 141 to the substrate holder 120 and returned at a corresponding outlet 142 from the substrate holder 120. The flow of the first heat-transfer fluid issues at a first flow rate (or velocity) and a first temperature from a first heat exchanger (or chiller) 150. The second fluid channel 145 is configured to circulate a second heat-transfer fluid provided at a corresponding inlet 146 to the substrate holder 120 and returned at a corresponding outlet 147 from the substrate holder 120. The second heat-transfer fluid issues at a second flow rate (or velocity) and a second temperature from a second heat exchanger (or chiller) 155.

For example, the first and second heat exchangers 150 and 155, respectively, can include a Model No. UBRPD5A-1T4 chiller, commercially available from Daikin Industries Limited. The first and second heat exchangers 150, 155 can be configured to operate with heat-transfer fluids including, for instance, at least one of water, or a dielectric fluid, such as Fluorinert or Galden HT-135. As would be understood by one of ordinary skill in the art, the first and second heat transfer fluids may be the same or different fluids. Similarly, the first and second flow rates may be the same or different depending on process requirements.

Referring still to FIG. 1, a controller 160 comprises a microprocessor, memory, and a digital I/O port capable of generating control voltages sufficient to communicate and activate inputs to material processing system 100 as well as monitor outputs from material processing system 100. Moreover, controller 160 can be coupled to and can exchange information with the gas injection system 118, the vacuum pumping system 130, the first heat exchanger 150, the second heat exchanger 155, a high voltage direct current (DC) voltage supply, not shown, facilitating electrostatic clamping of the substrate 135, and a backside gas supply system, also not shown. For example, a program stored in the memory can be utilized to activate the inputs to the aforementioned components of material processing system 100 according to a process recipe in order to perform the method of controlling a substrate temperature. One example of controller 160 is a DELL PRECISION WORKSTATION 640™, available from Dell Corporation, Austin Tex.

Controller 160 can be locally located relative to the material processing system 100, or it can be remotely located relative to the material processing system 100. For example, controller 160 can exchange data with material processing system 100 using at least one of a direct connection, an intranet, and the internet. Controller 160 can be coupled to an intranet at, for example, a customer site (i.e., a device maker, etc.), or it can be coupled to an intranet at, for example, a vendor site (i.e., an equipment manufacturer). Additionally, for example, controller 160 can be coupled to the internet. Furthermore, another computer (i.e., controller, server, etc.) can, for example, access controller 160 to exchange data via at least one of a direct connection, an intranet, and the internet.

According to the present invention, the temperature of substrate holder 120, and the spatial distribution of temperature can be controlled using two or more thermal zones, such as the first thermal zone (center) and the second thermal zone (peripheral) depicted in exemplary FIG. 1. As shown in FIG. 1, each thermal zone possesses a fluid channel independently coupled to a heat exchanger, wherein the velocity (or flow rate) of the heat-transfer fluid, or the temperature of the heat-transfer fluid, or both can be adjusted to attain a controlled substrate holder temperature. Such a configuration allows the ability to control spatial distribution of temperature across the substrate holder. For example, either a strong central-peaked temperature profile or a strong edge-peaked temperature profile of the top surface 121 of the substrate holder 120 can be obtained or maintained. Alternatively, a substantially uniform temperature profile can be obtained. Thus, unlike the single temperature control channel described in the Background section above, the present invention allows the use of a temperature profile to compensate for uneven backside gas pressure or thermal non-uniformities.

In addition, the inventive configuration provides for more rapid change in the temperature of the substrate. In particular, the present inventors have recognized that the use of flow rate to control the temperature provides a faster temperature change than using the chiller to control the temperature of the heat transfer fluid. Moreover, the use of two chillers independently coupled to the heat control channels provides a more rapid overall temperature change than the single channel-single chiller configuration of the prior art. Still further, rapid temperature profile changes to the top surface 121 of the substrate holder can be obtained by flow rate changes in the heat transfer fluid supplied to either the first fluid channel 140, the second fluid channel 145, or both. Capabilities for rapid temperature and/or temperature profile changes utilizing flow rate changes in the heat-transfer fluid can be enhanced when the temperature of the heat-transfer fluid is regulated as well.

According to another illustrated embodiment depicted in FIG. 2, the substrate holder 120 can further include two or more temperature sensors 170 and 175 located proximate the first (center) thermal zone and the second (peripheral) thermal zone, respectively. Temperature sensors can include a thermocouple (e.g. a K-type thermocouple). Alternatively, temperature sensors can include an optical fiber thermometer commercially available from Advanced Energies, Inc. (1625 Sharp Point Drive, Fort Collins, Colo., 80525), Model No. OR2000F capable of measurements from 50 to 2000 C and an accuracy of plus or minus 1.5 C, or a band-edge temperature measurement system as described in pending U.S. patent application Ser. No. 10/168,544, filed on Jul. 2, 2002, entitled “Method of wafer band-edge measurement using transmission spectroscopy and a processor controlling the temperature uniformity of a wafer”, the contents of which are incorporated herein by reference in their entirety. The two or more temperature sensors 170 and 175 can provide temperature measurements to controller 160 as feedback to a control algorithm implemented to obtain a target temperature distribution.

For example, when the heat-transfer fluid temperature is less than the substrate holder temperature, an increase in the flow rate (or velocity) of the heat-transfer fluid can affect a decrease in the substrate holder temperature. Alternatively, a decrease in the flow rate (or velocity) of the heat-transfer fluid can affect an increase in the substrate holder temperature. Additionally, for example, when the heat-transfer fluid temperature is greater than the substrate holder temperature, an increase in the flow rate (or velocity) of the heat-transfer fluid can affect an increase in the substrate holder temperature. Alternatively, a decrease in the flow rate (or velocity) of the heat-transfer fluid can affect a decrease in the substrate holder temperature.

According to another illustrated embodiment depicted in FIG. 3, a material processing system 200 can, for example, be similar to the embodiments of FIG. 1 and FIG. 2, and can comprise a substrate holder 220 further including a thermal insulator 225 positioned between the first fluid channel 140 and the second fluid channel 145. The thermal insulator 225 is substantially concentric with the first fluid channel 140 and the second fluid channel 145. The thermal insulator 225 is inserted between the first fluid channel 140 and the second fluid channel 145 to laterally insulate the controllable thermal zones in the substrate holder 220. Thermal insulator 225 can be any material or combination of materials with a low thermal conductivity (relative to the thermal conductivity of the substrate holder 220). Alternatively, thermal insulator 225 can include an insulator with an adjustable thermal conductivity, such as a gas gap with variable pressure. Additional details can be found in pending U.S. patent application Ser. No. 10/721,500, filed on Nov. 26, 2003, entitled “Method and system for substrate temperature profile control”, which is herein incorporated by reference in its entirety.

According to another illustrated embodiment depicted in FIG. 4, a material processing system 300 can, for example, be similar to the embodiments of FIG. 1, FIG. 2, and FIG. 3, and can comprise a substrate holder 320 further including two or more temperature control elements 331 and 332. Each temperature control element, i.e., 331 and 332, can, for example, include another fluid channel for flowing a heat-transfer fluid, a resistive heating element, or a thermoelectric device (or array thereof). Additionally, substrate holder 320 can optionally include thermal insulator 325. The use of the two or more temperature control elements, located above the first and second fluid channels 140 and 145, can provide additional control for heating and cooling substrate 135.

According to another illustrated embodiment depicted in FIG. 5, a material processing system 400 can, for example, be similar to the embodiments of FIG. 1, FIG. 2, FIG. 3, and FIG. 4, and can comprise a substrate holder 420 further including two or more controllable insulation elements 441 and 442. Each controllable insulation element, i.e., 441 and 442, can include a gas gap having a variable pressure in order to vertically control the flow of heat within substrate holder 420. Additional details can be found in U.S. Provisional Ser. No. 60/458,053, filed on Mar. 28, 2003, entitled “Method and system for temperature control of a substrate”, the entire contents of which are herein incorporated by reference.

While the embodiments above illustrate two separate thermal zones, those skilled in the art will readily appreciate other embodiments with differing numbers of thermal channels that may or may not be separated by some number of thermal insulators.

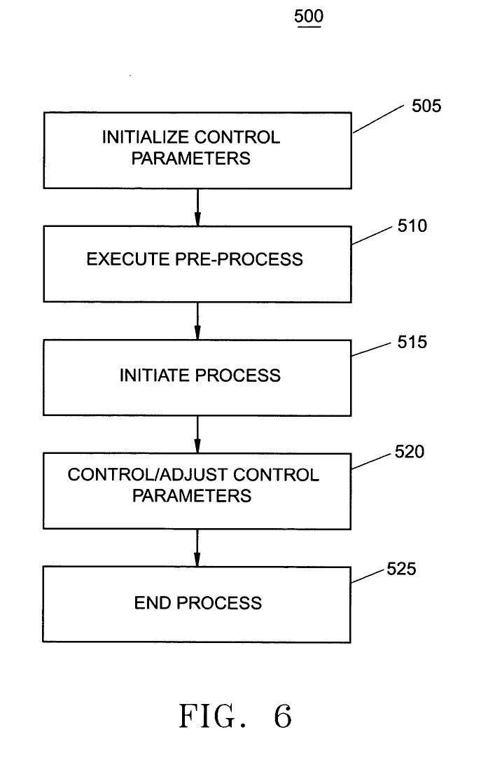

FIG. 6 presents a flowchart describing a method 500 of controlling the temperature profile of a substrate on a substrate holder in a processing system. The temperature profile scheme can pertain to multiple process steps for a process in a process system. The substrate holder can comprise one of those described in FIG. 1, FIG. 2, FIG. 3, FIG. 4, or FIG. 5. The method 500 begins in 505 with initializing the control parameters for controlling the temperature profile of the substrate. As used herein, “controlling the temperature profile” means independently controlling different spatial regions of a substrate holder to achieve either a uniform or non-uniform substrate temperature. The control parameters comprise the input parameters for a first thermal zone and the input parameters for a second thermal zone. The control parameters can further comprise, but are not limited to, the input parameters for the electrostatic clamp HV DC power supply voltage, the input parameter for the electrostatic clamp HV DC power supply current, the input parameters for the backside gas supply system, the input parameters of the gas injection system, the input parameters of the vacuum pumping system, etc. The input parameters for the first and second thermal zones can, for example, comprise a fluid flow rate (or velocity), or a fluid temperature, or both. The input parameter for the electrostatic clamp HV DC power supply voltage can, for example, comprise a clamping voltage. The input parameter for the electrostatic clamp HV DC power supply current can, for example, comprise a clamping current. The input parameter for a backside gas supply system can, for example, comprise a backside flow rate, a backside pressure, or a backside gas type. The input parameter for a gas injection system can, for example comprise a gas injection flow rate or rates, a gas injection pressure or pressures, or a gas injection gas type or types.

In 510 the control parameters established in 505 can be set in order to perform at least one of pre-processing the substrate, the substrate holder, or the processing system.

In 515 the process is initiated in the processing system for treating the substrate, and, in 520 the control parameters are controlled and/or adjusted. The control parameters can be controlled and/or adjusted according to a predetermined process recipe. Alternately, the control parameters can be controlled and/or adjusted according to a comparison of temperature measurements using temperature-sensing devices (temperature sensors) with process conditions dictated by a process recipe. Alternately, the control parameters can be controlled and/or adjusted according to a combination of a predetermined process recipe and a comparison of temperature measurements using temperature sensing devices with process conditions dictated by a process recipe.

In 525, the process is terminated, and, thereafter, the control parameters can, optionally, be controlled and/or adjusted in order to post-process at least one of the substrate, the substrate holder, or the processing system.

Although only certain exemplary embodiments of this invention have been described in detail above, those skilled in the art will readily appreciate that many modifications are possible in the exemplary embodiments without materially departing from the novel teachings and advantages of this invention. Accordingly, all such modifications are intended to be included within the scope of this invention.

1. A system for controlling the temperature of a substrate comprising:
a substrate holder having a first fluid channel located in a first thermal zone in said substrate holder, and a second fluid channel located in a second thermal zone in said substrate holder;
a first heat exchanger coupled to said first fluid channel, and configured to supply a first heat transfer fluid at a first flow rate to said first fluid channel; and
a second heat exchanger coupled to said second fluid channel, and configured to supply a second heat transfer fluid at a second flow rate to said second fluid channel.

2. The system of claim 1, further comprising:
a first temperature sensor located proximate said first thermal zone;
a second temperature sensor located proximate said second thermal zone;
a controller coupled to said first temperature sensor and said second temperature sensor, and configured to adjust said first flow rate or said second flow rate or both until a desired substrate temperature is achieved.

3. The system of claim 2, wherein said first temperature sensor and said second temperature sensor include a thermocouple, or an optical temperature measurement device.

4. The system of claim 3, wherein said optical temperature measurement device includes an optical thermometer.

5. The system of claim 1, wherein at least one of said first fluid channel and said second fluid channel is substantially circular in the plane of the top surface of said substrate holder.

6. The system of claim 1, wherein said first fluid channel and said second fluid channel are concentric about a central axis of said substrate holder.

7. The system of claim 1, further comprising:
at least one insulator, having a lower coefficient of thermal conductivity than said substrate holder, said at least one insulator being disposed between said first thermal zone and said second thermal zone.

8. The system of claim 1, further comprising:
one or more temperature control elements located proximate to said first fluid channel and said second fluid channel.

9. The system of claim 8, wherein said one or more temperature control elements include one or more fluid channels, one or more resistive heating elements, one or more thermoelectric devices, or a combination thereof.

10. The system of claim 8, further comprising:
one or more controllable insulation elements located between said one or more temperature control elements, and said first fluid channel and said second fluid channel.

11. The system of claim 1, further comprising:
a first temperature sensor located proximate said first thermal zone;
a second temperature sensor located proximate said second thermal zone;
a controller coupled to said first temperature sensor and said second temperature sensor, and configured to adjust a temperature of said first heat transfer fluid or said second heat transfer fluid or both until a desired substrate temperature is achieved.

12. The system of claim 1, wherein said first and second fluids comprise a same fluid.

13. The system of claim 1, wherein said first and second heat exchangers are configured to provide said first and second flow rates at substantially the same flow rate.

14. The system of claim 2, wherein said controller is further configured to adjust said first flow rate or said second flow rate or both until a desired substrate temperature profile is achieved.

15. A method of controlling temperature of a substrate held on a substrate holder comprising:
providing a first heat transfer fluid to a first thermal zone in said substrate holder;
providing a second heat transfer fluid to a second thermal zone in said substrate holder; and
controlling a flow rate of said first heat transfer fluid or said second heat transfer fluid or both to control a temperature profile of said substrate.

16. The method of claim 15, further comprising:
initializing one or more parameters for controlling the temperature profile of said substrate wherein said one or more parameters includes one or more of a flow rate of said first heat transfer fluid, and a flow rate of said second heat transfer fluid;
initiating a process in said processing system;
adjusting said one or more parameters; and
terminating said process.

17. The method of claim 16, further comprising controlling a temperature of said first heat transfer fluid or said second heat transfer fluid or both to control said temperature profile of said substrate.

18. A system for controlling the temperature of a substrate comprising:
a substrate holder having a first thermal zone in said substrate holder, and a second thermal zone in said substrate holder;
means for independently controlling a temperature of said first and second thermal zones of said substrate holder to provide a temperature profile for said substrate holder.
